(19) United States
(12) Patent Application Publication
(10) Pub. No.: US 2007/0114208 A1
(43) Pub. Date: May 24, 2007

(54) SUBSTRATE TREATING METHOD AND APPARATUS

(76) Inventor: Hiroaki Takahashi, Kyoto (JP)

Correspondence Address: OSTROLENK FABER GERB & SOFFEN, 1180 AVENUE OF THE AMERICAS, NEW YORK, NY, 100368403, US

(21) Appl. No.: 11/561,586

(22) Filed: Nov. 20, 2006

(30) Foreign Application Priority Data
Nov. 21, 2005 (JP) 2005-335835
Sep. 14, 2006 (JP) 2006-249726

(51) Int. Cl. B44C 1/22; H01L 21/306; C23F 1/00

(52) U.S. Cl. 216/83; 156/345.11; 156/345.31

(57) ABSTRACT

A substrate treating method includes heating a substrate having an ion-implanted film formed on a surface thereof in an oxygen environment, and removing the film from the surface of the substrate by supplying a treating solution containing sulfuric acid and hydrogen peroxide solution or a treating solution containing ozone to the substrate after the heating step.

### BACKGROUND OF THE INVENTION

(1) Field of the Invention

This invention relates to a substrate treating method and apparatus for treating substrates such as semiconductor wafers (hereinafter simply called substrates) with a treating solution. More particularly, the invention relates to a technique of removing film formed on a surface of a substrate and implanted with ions.

(2) Description of the Related Art

With increasingly fine patterns formed in recent years, the quantity of ions implanted into wafers has been on the increase. The largest quantity of ion implantation today is as many as about 10×10¹⁶ particles/cm² for arsenic, for example. In time of such ion implantation, generally, photoresist film is used as a mask in order to prevent the ions from being implanted outside target regions. The photoresist film is stripped off and removed after the ion implantation. The more ions are implanted, the more difficult it is to strip off the photoresist film because of an alteration in its surface quality. Thus, a process known as ashing is carried out in order to remove the mask after the ion implantation.

Conventional ashing apparatus include a plasma ashing apparatus that has a chamber for generating plasma and ashing photoresist film with hot plasma for removal (see Japanese Unexamined Patent Publication No. 2000-173991, for example).

The above conventional apparatus has the following drawback.

The conventional apparatus using plasma can damage the pattern on the wafer. This poses a problem of lowering yield.

To avoid such an inconvenience, it has been proposed to perform a wet process using a treating solution, instead of ashing. However, it is extremely difficult to strip off photoresist film implanted with a large quantity of ions (high-dose photoresist film). In practice, there is no choice but to perform ashing.

### SUMMARY OF THE INVENTION

This invention has been made having regard to the state of the art noted above, and its object is to provide a substrate treating method and apparatus for performing an effective pretreatment to be capable of stripping off and removing high-dose film through a wet process, without ashing.

To fulfill the above object, Inventor has made intensive research and attained the following findings.

Inventor has conducted experiment in which substrates coated with high-dose film were preheated at various temperatures before treating the substrates with a treating solution including sulfuric acid and hydrogen peroxide solution. As shown in FIGS. 1 through 6, the substrates were treated with the treating solution after performing, as pretreatment, heating treatment at high temperatures of 300 to 500° C. in an oxygen environment, such temperatures not being adopted for ordinary treatment. It has been found as a result that the high-dose film, which could not be stripped off only by the treatment with the treating solution, is easily stripped off the substrates.

Based on the above findings, this invention provides a substrate treating method comprising heating a substrate having an ion-implanted film formed on a surface thereof in an oxygen environment; and removing the film from the surface of the substrate by supplying a treating solution containing sulfuric acid and hydrogen peroxide solution or a treating solution containing ozone to the substrate after the heating step.

The “oxygen environment” here means that an oxygen concentration in a gas is 0 to 21 [vol %]. According to this invention, the heating step carried out in the oxygen environment ashes the film to a certain degree, though less than by an ashing process. By subsequently carrying out a wet process with the treating solution, the film ashed to a certain degree can easily be stripped off and removed completely. Thus, without performing an ashing process, even high-dose film can be stripped off and removed completely. As a result, a pattern on the substrate is free from damage, realizing an improved yield.

The above method may further comprise cooling the substrate to normal temperature after said heating a substrate and before said removing the film.

The same effect can be produced even when the substrate returns to normal temperature in the cooling. Thus, the same effect can be produced even when the handling of the substrate requires its cooling or when an idle time occurs between the heating and removing.

In this invention, the heating may be executed at a heating temperature in a range of 300 to 500° C.

This temperature range achieves ashing to an extent of enabling an effective removal with the treating solution in the removing. Heating at temperatures below 300° C. will result in insufficient ashing. Heating at temperatures above 500° C. will cause an inconvenience of affecting a distribution of impurities added to the substrate, for example.

In another aspect of this invention, a substrate treating apparatus is provided which comprises a heating unit for heating a substrate having an ion-implanted film formed on a surface thereof in an oxygen environment; a removing unit for removing the film from the surface of the substrate by supplying a treating solution containing sulfuric acid and hydrogen peroxide solution or a treating solution containing ozone to the substrate after being in the heating unit; and a transport mechanism for transporting the substrate from the heating unit to the removing unit.

The “oxygen environment” herein means that an oxygen concentration in a gas is 0 to 21 [vol %]. According to this invention, the heating unit carried out heating treatment of the substrate in the oxygen environment to ash the film to a certain degree. Then, the transport mechanism transports the substrate to the removing unit. In the removing unit, the treating solution is supplied to the substrate, whereby the film formed on the substrate, even if high-dose film, is stripped off easily and removed completely. As a result, a pattern on the substrate is free from damage, realizing an improved yield.

### BRIEF DESCRIPTION OF THE DRAWINGS

For the purpose of illustrating the invention, there are shown in the drawings several forms which are presently preferred, it being understood, however, that the invention is not limited to the precise arrangement and instrumentalities shown.

FIG. 1 is a view illustrating a substrate treating method in Embodiment 1, which shows surface conditions immediately after heating at 300° C.;

FIG. 2 is a view illustrating the substrate treating method in Embodiment 1, which shows surface conditions immediately after treatment with a mixture of sulfuric acid and hydrogen peroxide solution after heating at 300° C.;

FIG. 3 is a view illustrating a substrate treating method in Embodiment 1, which shows surface conditions immediately after heating at 450° C.;

FIG. 4 is a view illustrating the substrate treating method in Embodiment 1, which shows surface conditions immediately after treatment with the mixture of sulfuric acid and hydrogen peroxide solution after heating at 450° C.;

FIG. 5 is a view illustrating a substrate treating method in Embodiment 1, which shows surface conditions immediately after heating at 500° C.;

FIG. 6 is a view illustrating the substrate treating method in Embodiment 1, which shows surface conditions immediately after treatment with the mixture of sulfuric acid and hydrogen peroxide solution after heating at 500° C.;

FIG. 7 shows surface conditions of substrates cooled after a heating process, in which FIG. 7A shows a result of air cooling, and FIG. 7B shows a result of water cooling;

FIG. 8 is a view showing an outline of a substrate treating apparatus in Embodiment 2;

FIG. 9 is a view showing an outline of a substrate treating apparatus in Embodiment 3; and

FIG. 10 schematically shows a preferred construction of an arm, in which FIG. 10A is a plan view, and FIG. 10B is a side view.

### DESCRIPTION OF THE PREFERRED EMBODIMENTS

Embodiments of this invention will be described hereinafter with reference to the drawings.

### Embodiment 1

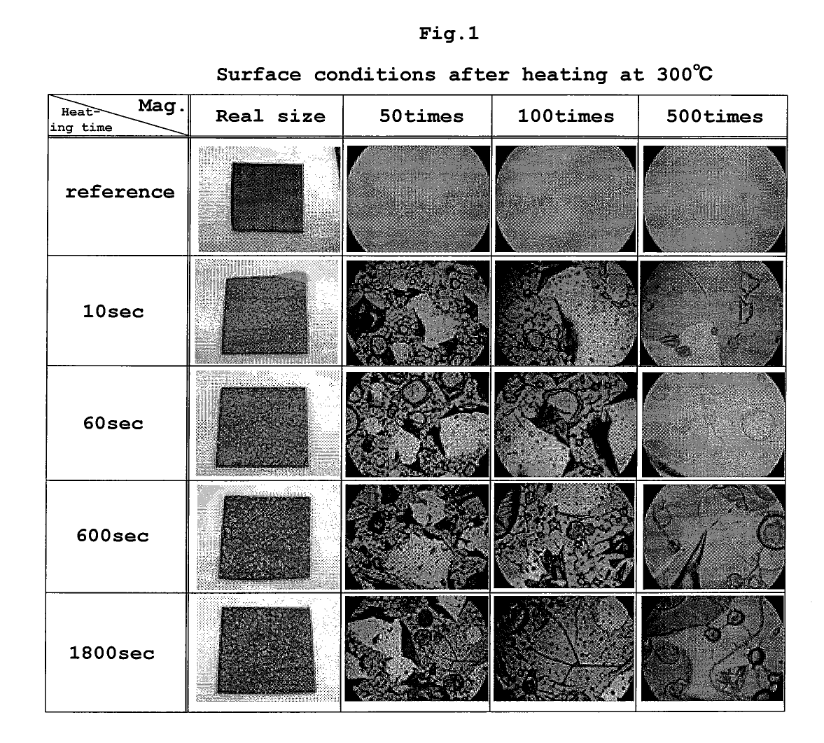

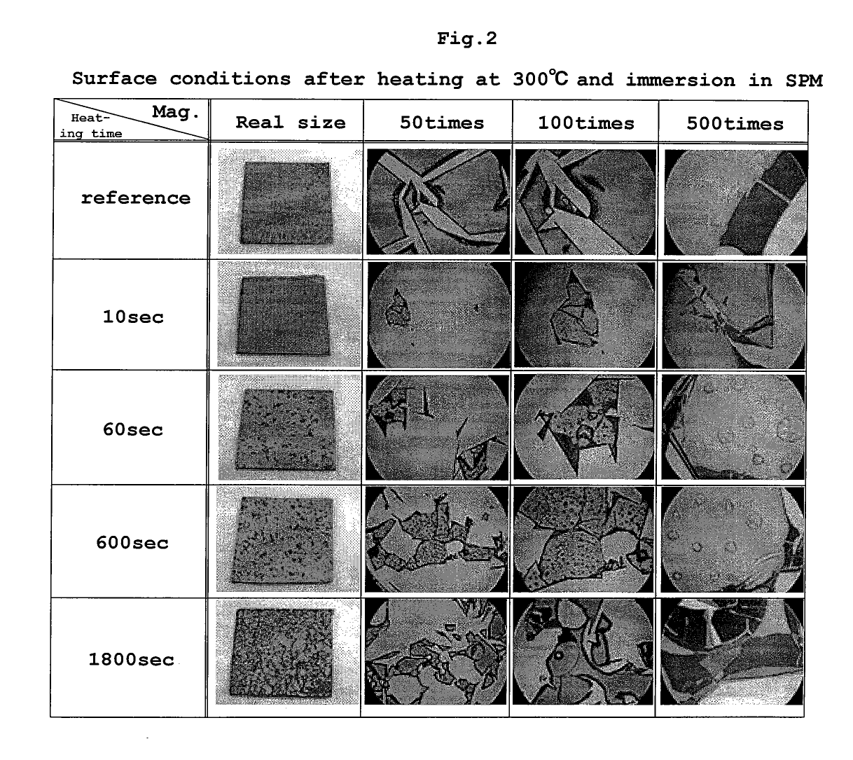

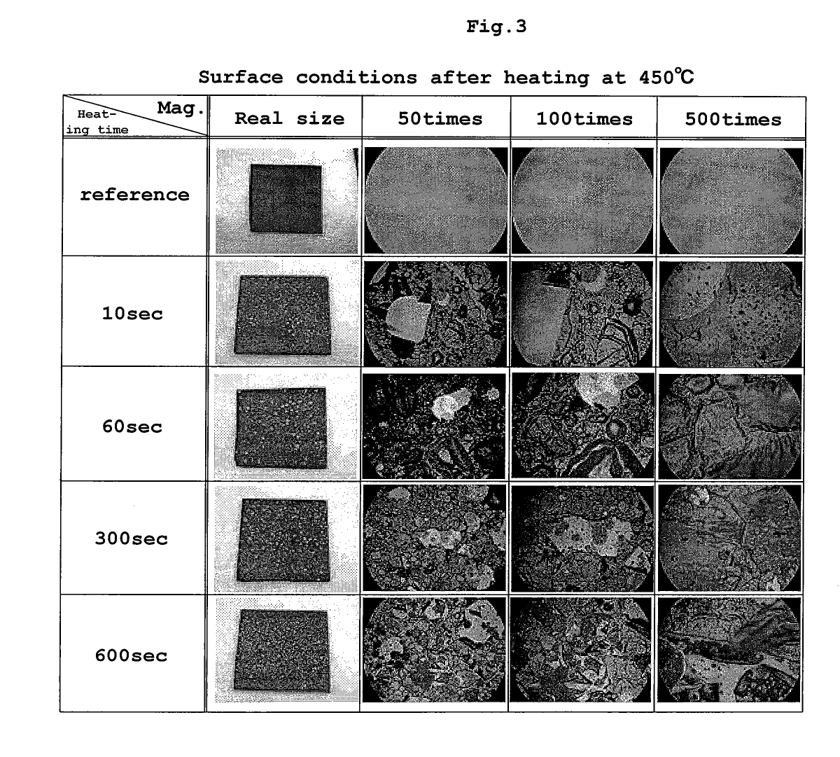

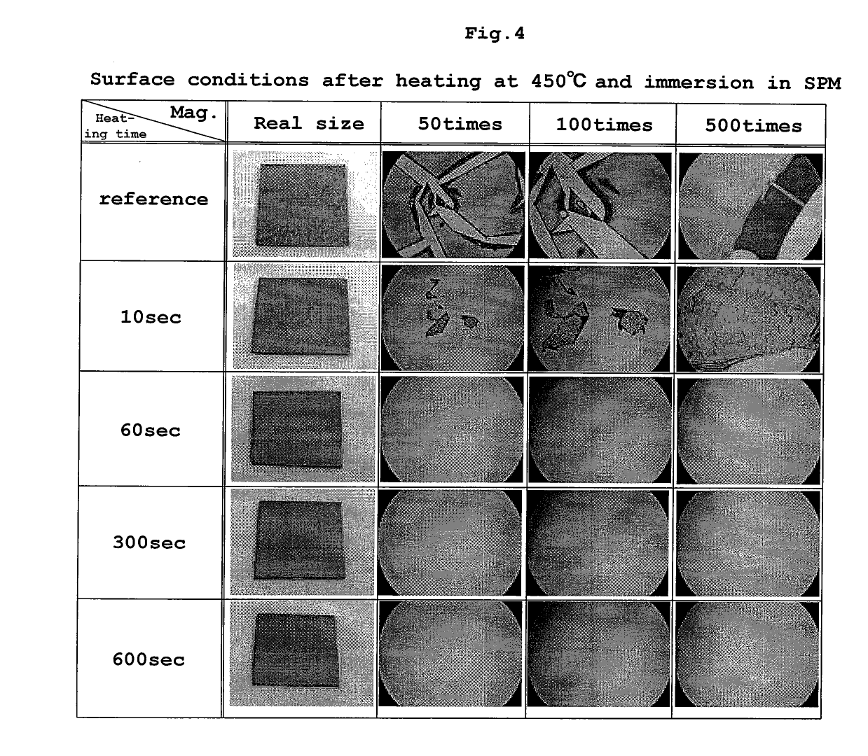

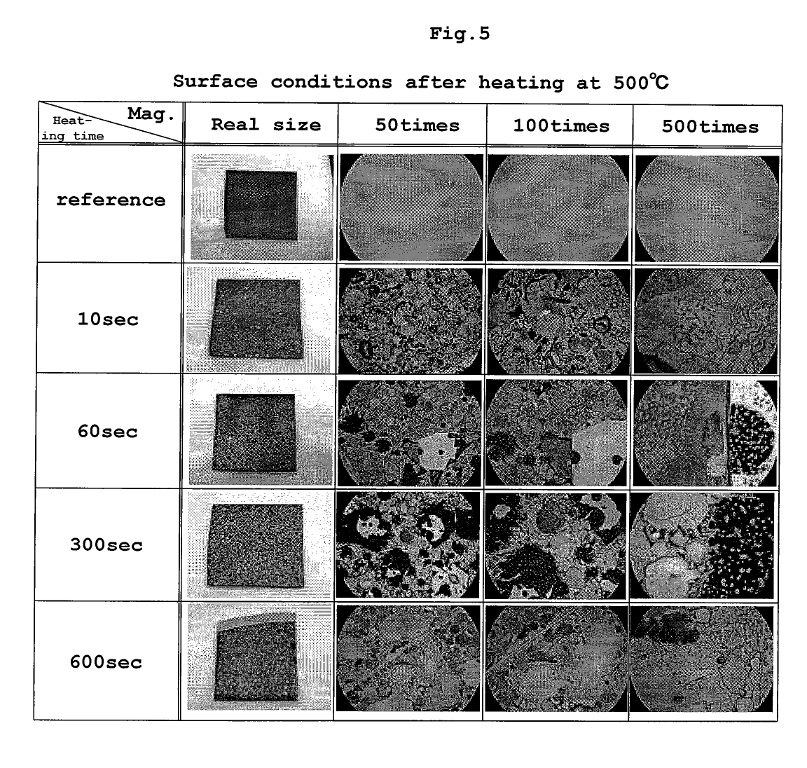

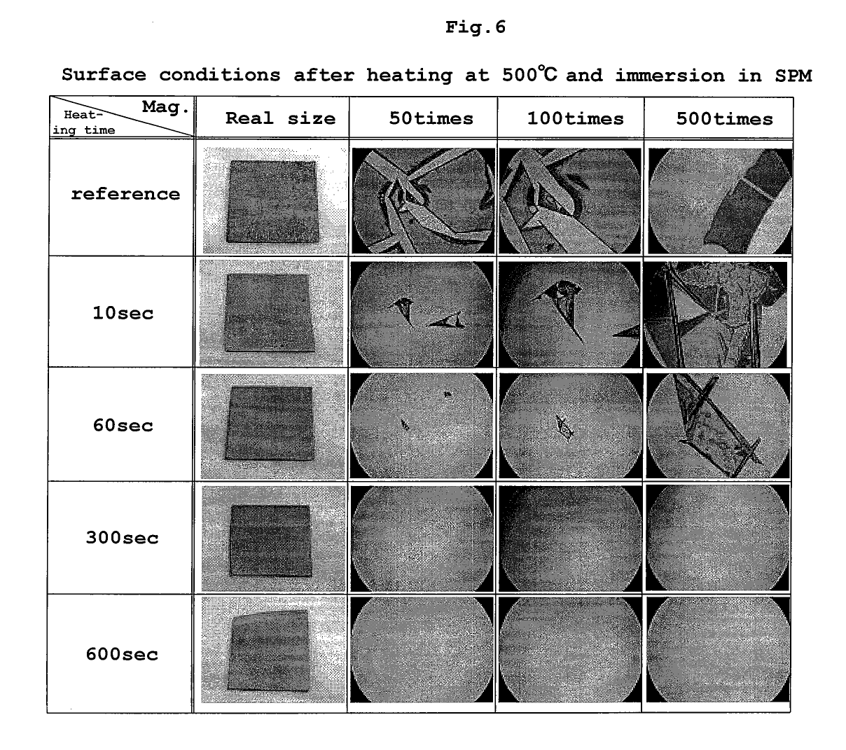

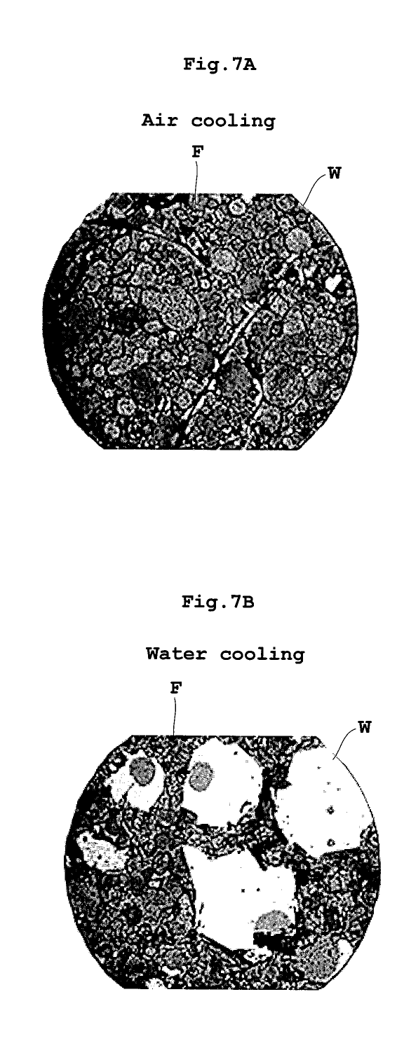

Embodiment 1 of this invention will be described with reference to FIGS. 1 through 7. FIG. 1 is a view illustrating a substrate treating method in Embodiment 1, which shows surface conditions immediately after heating at 300° C. FIG. 2 is a view illustrating the substrate treating method in Embodiment 1, which shows surface conditions immediately after treatment with a mixture of sulfuric acid (H₂SO₄) and hydrogen peroxide solution (H₂O₂) (SPM: Sulfuric acid/hydrogen Peroxide Mixture) after heating at 300° C. FIG. 3 is a view illustrating a substrate treating method in Embodiment 1, which shows surface conditions immediately after heating at 450° C. FIG. 4 is a view illustrating the substrate treating method in Embodiment 1, which shows surface conditions immediately after treatment with the mixture of sulfuric acid and hydrogen peroxide solution (SPM) after heating at 450° C. FIG. 5 is a view illustrating a substrate treating me thod in Embodiment 1, which shows surface conditions immediately after heating at 500°C. FIG. 6 is a view illustrating the substrate treating method in Embodiment 1, which shows surface conditions immediately after treatment with the mixture of sulfuric acid and hydrogen peroxide solution (SPM) after heating at 500° C. FIG. 7 shows surface conditions of substrates cooled after a heating process, in which FIG. 7A shows a result of air cooling, and FIG. 7B shows a result of water cooling. In FIGS. 1 through 7, the vertical direction represents heating time and the horizontal direction magnification of an optical microscope. In time of heating, the substrate is kept in contact with a heat plate. The mixing ratio of sulfuric acid to hydrogen peroxide solution in the SPM solution is 0.5. The immersion time of the substrate in the SPM solution is 30 seconds.

Photoresist film was coated on wafer, and an ion implantation process was carried out by using this photoresist film as a mask. The photoresist film was KrF resist, which was coated in a thickness of 0.8 [μm] on bare silicon wafer. The ion implantation used arsenic (As) as impurities, with dose energy=40 [KeV], and dose=1×10¹⁶ [particles/cm²]. Thus, the photoresist film on the wafer is what is called high-dose film. The “oxygen environment” herein means that an oxygen concentration in a gas is 0 to 21 [vol %]. The oxygen concentration in the gas is maintained by varying a supply balance of oxygen and nitrogen.

Subsequently, the wafer was subjected to a heating step carried out at 300° C., 450° C. and 500° C. in a non-heated oxygen environment. Resulting conditions are shown in FIGS. 1, 3 and 5. Next, immediately after the heating step, a removing step was carried out by immersing the wafer, for a predetermined time, in a treating solution which consisted of the SPM solution, i.e. the mixture of sulfuric acid and hydrogen peroxide solution. The conditions of the wafer withdrawn from the treating solution are shown in FIGS. 2, 4 and 6.

FIG. 1 shows wafers immediately after the heating at 300° C. It is seen that, although the photoresist film alters in quality in a short time of about 10 seconds, more film remains unstripped as the heating time is extended. Presumably, this is because the hardening and adhesion of the photoresist film depend on the heating time.

FIG. 2 shows wafers having been immersed in the treating solution consisting of the SPM solution, after the heating treatment at 300° C. It is seen that, while the film is stripped off sufficiently even in a short time of about 10 seconds, more film remains unstripped as the heating time is extended. Presumably, this is because the hardening and adhesion of the photoresist film depend on the heating time, as noted above.

FIG. 3 shows wafers immediately after the heating at 450°C. A visual observation has confirmed that the photoresist film altered in quality even in a short time of about 10 seconds, and discolored depending on the heating time.

FIG. 4 shows wafers having been immersed in the treating solution consisting of the SPM solution, after the heating treatment at 450° C. It is seen that the photoresist film can be stripped off sufficiently even in a short time of about 10 seconds, by immersion in the SPM solution. Since the photoresist film stripping performance improves depending on the heating time, the heating at 450° C., presumably, renders carbonization stronger than the hardening and adhesion of the photoresist film.

FIG. 5 shows wafers immediately after the heating at 500° C. A visual observation has confirmed that the photoresist film altered in quality even in a heating time of about 10 seconds, and the surface discolored depending on the heating time. The alteration in quality was remarkable as compared with the case of heating at 300° C. It is presumed from this fact that the heating at 500° C. causes stronger carbonization.

FIG. 6 shows wafers having been immersed in the treating solution consisting of the SPM solution, after the heating treatment at 500° C. The photoresist film can be stripped off sufficiently by heating treatment for a short time of about 10 seconds. Since the photoresist film stripping performance improves depending on the heating time, the heating at 500° C., presumably, renders carbonization stronger than the hardening and adhesion of the photoresist film.

Thus, by heating wafers W at high temperatures of 300 to 500° C. in an oxygen environment, the photoresist film is ashed to a certain degree, though less than by an ashing process. By subsequently carrying out a wet process with the treating solution consisting of the SPM solution, photoresist film F ashed to a certain degree can easily be stripped off and removed completely. Thus, without performing an ashing process, even high-dose photoresist film can be stripped off and removed completely. As a result, patterns on the wafers are free from damage, realizing an improved yield.

As noted above, the heating temperature, preferably, is in the range of 300 to 500° C. This temperature range achieves ashing to an extent of enabling an effective removal with the treating solution in the removing process. Heating at temperatures below 300° C. will result in insufficient ashing. Heating at temperatures above 500° C. could affect a distribution of impurities added to the wafer.

It has been checked whether the same effect as above is produced when the wafer W returns to normal temperature after the heating step and before the immersion in the treating solution consisting of the SPM solution (see FIG. 7).

Specifically, the surface of photoresist film F lost smoothness and considerably roughened when, after the heating step, the wafer W was cooled to normal temperature by air cooling in which the wafer W was left standing in the atmosphere (FIG. 7A), and when the wafer W was cooled to normal temperature by water cooling in which the wafer W was immersed in deionized water at normal temperature (FIG. 7B). That is, the photoresist film F was greatly damaged and, naturally, was stripped off and removed with ease as described above when immersed in the treating solution. It will be understood from this result that, by heating the wafer W at a high temperature of 300 to 500° C. in an oxygen environment, the photoresist film F can be stripped off and removed easily with the treating solution consisting of the SPM solution.

Thus, the same effect can be produced even when the wafer W returns to normal temperature after the heating step. The same effect can be produced even when the handling of wafer W requires its cooling or when an idle time occurs between the heating step and removing step.

### Embodiment 2

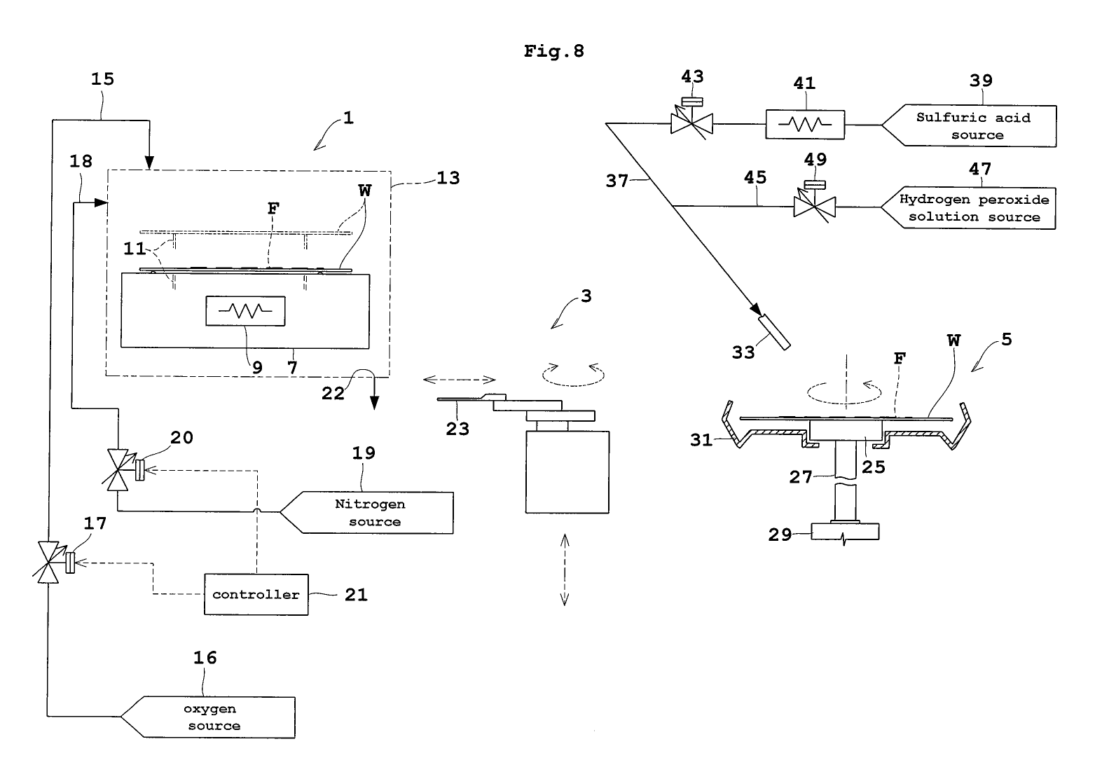

Next, Embodiment 2 of this invention will be described with reference to FIG. 8.

FIG. 8 is a view showing an outline of a substrate treating apparatus in Embodiment 2.

The substrate treating apparatus, which can appropriately implement the substrate treating method described Embodiment 1 above, includes a heating unit 1, a transport unit 3 and a removing unit 5, for example.

The heating unit 1 has a heat plate 7 for supporting a wafer W. The heat plate 7, preferably, is the proximity treatment type for heat-treating the wafer W with a high degree of uniformity over the surface thereof, for example. The heat plate 7 has a heater 9 embedded therein for heating the heat plate 7 at a temperature range of 300 to 500° C. The heat plate 7 has support pins 11 extendible and retractable relative to the surface thereof. The pins 11 extend above the surface when transferring the wafer W to and from the transport unit 3, and retract below the surface in time of heat treatment.

The heat plate 7 is enclosed in a chamber 13. The chamber 13 has, connected thereto, one end of oxygen supply piping 15. The other end of the oxygen supply piping 15 is connected to an oxygen source 16 (oxygen supplying device). The oxygen supply piping 15 has a control valve 17 mounted thereon for controlling a flow rate, circulation and non-circulation of oxygen gas (O₂). The chamber 13 has, connected thereto, one end of nitrogen supply piping 18 also. The other end of the nitrogen supply piping 18 is connected to a nitrogen source 19 (nitrogen supplying device). The nitrogen supply piping 18 has a control valve 20 mounted thereon for controlling a flow rate, circulation and non-circulation of nitrogen gas (N₂). The feed rate of the oxygen gas from the oxygen source 16 and the feed rate of the nitrogen gas from the nitrogen source 19 are adjusted by a controller 21 that controls the control valve 17 and control valve 20. With the controller 21 controlling the feed rate of the oxygen gas from the oxygen source 16 and the feed rate of the nitrogen gas from the nitrogen source 19, an oxygen concentration in the gas in the chamber 13 is adjusted to 0 to 21 [vol %]. The chamber 13 further includes an exhaust port 22 formed in one position thereof for exhausting the internal gas.

The transport unit 3, which corresponds to the transport mechanism in this invention, includes a vertically movable, rotatable, and extendible and contractible arm 23. This arm 23 transports the wafer W between the heating unit 1 and removing unit 5.

The removing unit 5 in Embodiment 2 is what is called the single substrate type that treats one wafer W at a time. Specifically, the removing unit 5 has a chuck 25 (holding mechanism) for supporting the wafer W in horizontal posture, a rotary shaft 27 connected to the lower end of the chuck 25, a motor 29 (actuator) for rotating the rotary shaft 27, and a scatter preventive cup 31 surrounding the chuck 25. The scatter preventive cup 31 collects a treating solution scattering from the wafer W. The scatter preventive cup 31 is vertically movable relative to the chuck 25.

A nozzle 33 (treating solution supplying device) is disposed above the spin center of the chuck 25. One end of piping 37 is connected to the nozzle 33, and the other end of the piping 37 is connected to a sulfuric acid source 39. The piping 37 has, arranged thereon from upstream to downstream, an in-line heater 41, and a control valve 43 for controlling a flow rate, and supply and non-supply. The in-line heater 41 heats sulfuric acid (H₂SO₄) flowing through the piping 37 to 100 to 200° C., for example. One end of piping 45 is connected to the piping 37, and the other end of the piping 45 is connected to a hydrogen peroxide solution source 47. The piping 45 has a control valve 49 mounted thereon for controlling a flow rate, and supply and non-supply of hydrogen peroxide solution (H₂O₂).

Next, the treatment by the above apparatus will be described.

First, the controller 21 opens the control valve 17 to supply oxygen gas at a predetermined flow rate from the oxygen supply piping 15 into the chamber 13, and opens the control valve 20 to supply nitrogen gas at a predetermined flow rate from the nitrogen supply piping 18 into the chamber 13, thereby to adjust the oxygen concentration in the gas in the chamber 13 to 0 to 21 [vol %]. At this time, the gas in the chamber 13 is exhausted at a low flow rate from the exhaust port 22. Further, the heater 9 is operated to set the surface of heat plate 7 to 300° C., for example, and the support pins 11 are extended above the surface of heat plate 7.

A shutter door, not shown, of the chamber 13 is opened, and the arm 23 of transport unit 3 transports a wafer W having high-dose photoresist film F formed on the surface thereof into the chamber 13. The wafer W is placed on the upper ends of support pins 11 which are then retracted below the surface of heat plate 7. The arm 23 is moved out of the chamber 13, and the shutter door not shown is closed. This state is maintained for a predetermined time (e.g. 180 seconds). During the heating process, the photoresist film F formed on the surface of wafer W is ashed as described in Embodiment 1.

After the predetermined time, the support pins 11 are extended, and the arm 23 is moved in past the shutter door not shown. The wafer W is transferred to the arm 23. The transport unit 3 places the wafer W on the chuck 25, while the scatter preventive cup 31 is in a lowered position. Then, the scatter preventive cup 31 is raised to a treatment position.

The motor 29 is driven to spin the wafer W at a predetermined speed. The spin speed is a low-speed spin of about 100 to 500 rpm, for example. Further, the heating temperature of in-line heater 41 is set to 120° C., and the control valve 43 is opened to supply heated sulfuric acid at a predetermined flow rate. The control valve 49 is opened to supply the hydrogen peroxide solution at normal temperature at a predetermined flow rate. As a result, the treating solution (SPM solution) consisting of the mixture of heated sulfuric acid and hydrogen peroxide solution is formed. The treating solution is supplied from the nozzle 33 to the surface of wafer W, thereby dissolving and removing the photoresist film F ashed in the heating process. Subsequently, deionized water is supplied from a nozzle, not shown, to the wafer W for cleaning treatment. Then, the wafer W is spun at high speed for spin drying.

Thus, in the heating unit 1, the wafer W is heated in the oxygen environment to ash the photoresist film F to some extent. In the removing unit 5, the treating solution is supplied to the wafer W whereby even high-dose photoresist film F formed on the wafer W is stripped off easily and removed completely. As a result, no damage is done to the pattern on the wafer W, to realize an improvement in yield.

### Embodiment 3

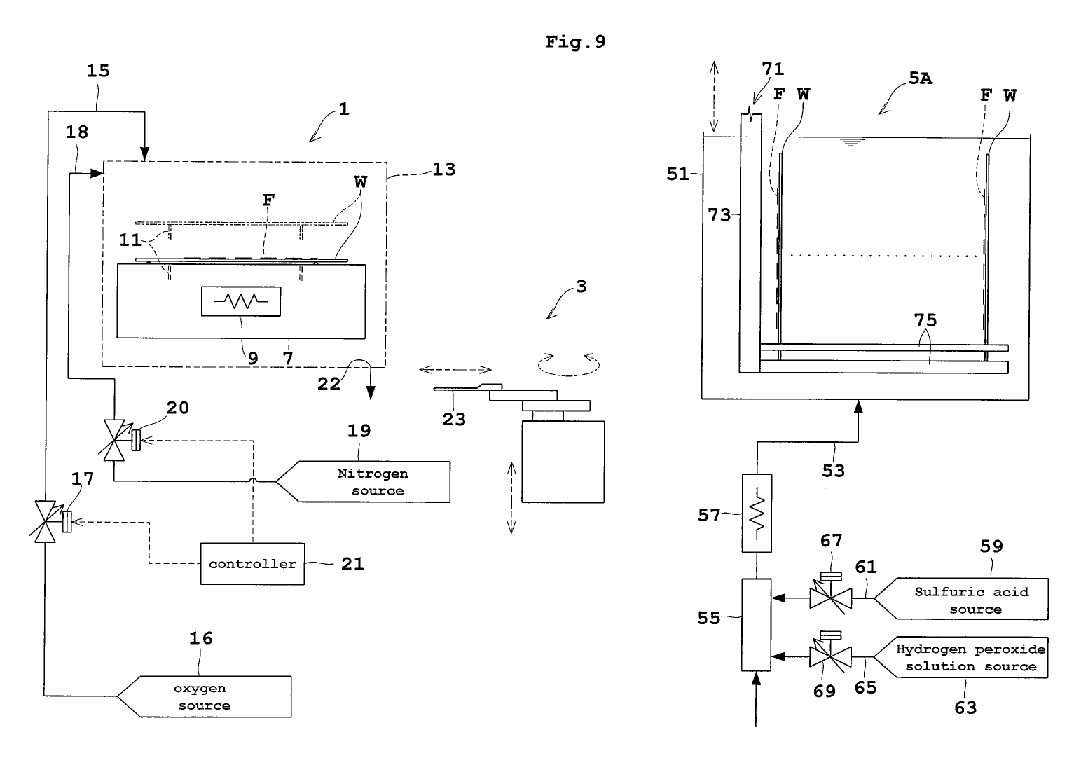

Next, Embodiment 3 of this invention will be described with reference to FIG. 9. FIG. 9 is a view showing an outline of a substrate treating apparatus in Embodiment 3. Like reference numerals are used to identify like parts which are the same as in Embodiment 2 and will not particularly be described again.

Embodiment 3 differs from Embodiment 2 in including a removing unit 5A of what is known as the batch type. The removing unit 5A has a treating tank 51 for storing a treating solution. The treating tank 51 has one end of piping 53 connected to the bottom thereof. The other end of piping 53 is connected to a deionized water source (treating solution supplying device) not shown. The piping 53 has a mixing valve 55 mounted thereon. The piping 53 has also an in-line heater 57 mounted thereon downstream of the mixing valve 55 for heating a treating solution in circulation up to a temperature as high as 200 to 300° C. The mixing valve 55 is in communication with a supply pipe 61 connected to a sulfuric acid source 59, and with a supply pipe 65 connected to a hydrogen peroxide solution source 63. The supply pipe 61 has a control valve 67 mounted thereon for controlling a flow rate, and supply and non-supply. The supply pipe 65 has a similar control valve 69 mounted thereon.

The removing unit 5A includes a lifter 71 (lift mechanism) vertically movable between a “treating position” in the treating tank 51 and a “transfer position” above the treating tank 51. The lifter 71 has a back plate 73 extending vertically, and support members 75 arranged to project horizontally from bottom positions of the lifter 71. Each support member 75 has a plurality of groove (not shown) for contacting and supporting lower edges of a plurality of wafers W in vertical posture. A posture change unit (not shown) is disposed between the transport unit 3 and removing unit 5A, for receiving a plurality of wafers W in horizontal posture from the transport unit 3 and, after receiving a predetermined number of wafers W, turning the wafers W to vertical posture.

With the substrate treating apparatus constructed as described above, each wafer W coated with photoresist film F undergoes heat treatment at high temperature (e.g. 300° C.) in the heating unit 1. Subsequently, the transport unit 3 transfers a plurality of wafers W to the lifter 71 of the removing unit 5A for film removing treatment in the treating tank 51.

Specifically, the removing treatment is carried out as follows, for example.

First, sulfuric acid and hydrogen peroxide solution are supplied from the sulfuric acid source 59 and hydrogen peroxide solution source 63 into the piping 53 through the mixing valve 55. The treating solution consisting of the SPM solution thereby formed and flowing through the piping 53 is heated by the in-line heater 57 to about 120° C., and is stored in the treating tank 51. Then, the lifter 71 is lowered to the “treating position”, and maintained there for a predetermined time (e.g. 180 seconds).

After elapse of the predetermined time, the control valves 67 and 69 are closed, and deionized water is supplied to the treating tank 51 through the piping 53. After a predetermined time of deionized water cleaning, the lifter 71 is raised to the “transfer position” to complete the process.

According to the construction in Embodiment 3, while securing the same effect as the preceding Embodiment 2, the batch process can treat an increased number of wafers W per unit time, and can thus treat large quantities of wafers W.

This invention is not limited to the foregoing embodiments, but may be modified as follows:

(1) In Embodiments 1-3 described above, the SPM solution containing sulfuric acid and hydrogen peroxide solution is used as the treating solution. Instead, for example, a treating solution having ozone dissolved in deionized water may be used.

(2) In Embodiments 2 and 3 described above, the transport unit 3 immediately transports wafers W heat-treated in the heating unit 1 to the removing units 5 and 5A for film removing treatment. However, as noted in Embodiment 1, the same effect can be produced even when temperature returns to normal temperature after the heat treatment. Thus, instead of providing the transport unit 3, the wafers W may be transported to the removing units 5 and 5A by manual handling after the temperature of wafers W returns to normal temperature.

(3) Embodiments 1-3 have been described by taking photoresist film for example. A different type of film may be used only if usable as a mask for ion implantation.

(4) In Embodiments 1-3 described above, the heating unit 1 includes the heat plate 7. Instead, for example, a lamp annealing device may be used.

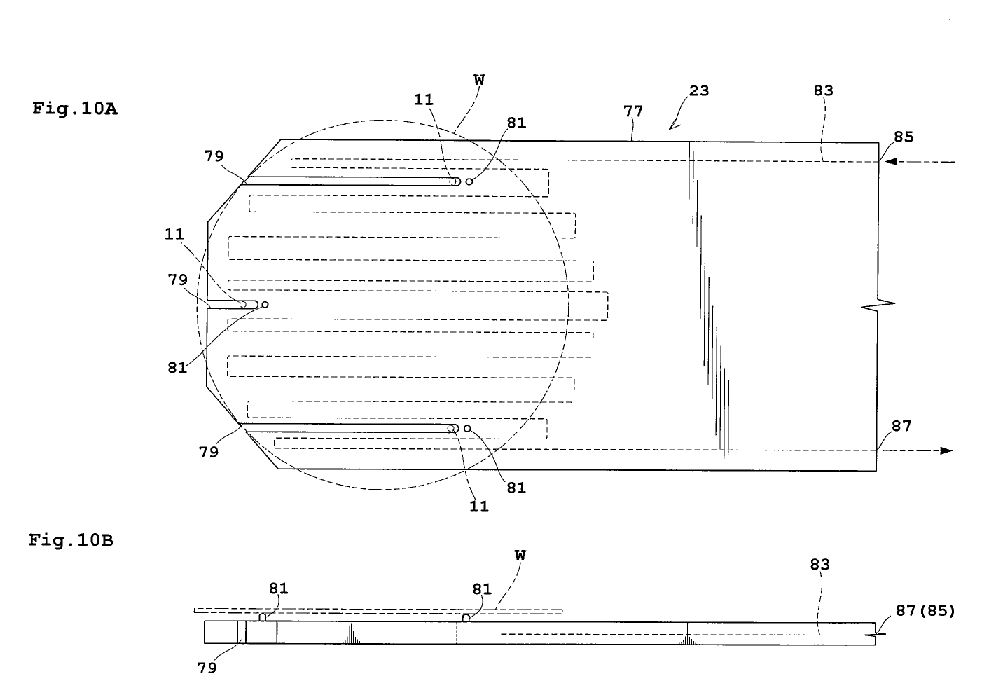

(5) In Embodiments 2 and 3 described above, the arm 23 of the transport unit 3, preferably, is constructed as shown in FIG. 10. FIG. 10 schematically shows a preferred construction of the arm 23, in which FIG. 10A is a plan view, and FIG. 10B is a side view.

This arm 23 includes a tongue-like main body 77 having three grooves 79 formed in a forward region thereof for allowing the three support pins 11 to move in and out through forward ends the grooves 79. Minute projections 81 are formed on the upper surface of the main body 77 adjacent the respective grooves 79. The main body 77 has a cooling water channel 83 formed therein and extending clear of the three grooves 79. The channel 83 has one end thereof defining an inlet 85, and the other end defining an outlet 87. Cooling water adjusted to a predetermined temperature is supplied to the inlet 85, and drained from the outlet 87, thereby cooling a heat-treated wafer W supported by the arm 23. The wafer W can be cooled to or near normal temperature during transport. Consequently, the wafer W may be handled with ease by the device of the next step even if this device has a construction incapable of handling hot wafers W. Where the transport unit 3 is equipped with this arm 23, the wafer W may be delivered to the next device by a transport unit having a transport arm movable into a space formed by the minute projections 81 and the upper surface of main body 77 of the arm 23.

This invention may be embodied in other specific forms without departing from the spirit or essential attributes thereof and, accordingly, reference should be made to the appended claims, rather than to the foregoing specification, as indicating the scope of the invention.

What is claimed is:

1. A substrate treating method comprising:
heating a substrate having an ion-implanted film formed on a surface thereof in an oxygen environment; and
removing the film from the surface of the substrate by supplying a treating solution containing sulfuric acid and hydrogen peroxide solution or a treating solution containing ozone to the substrate after said heating step.

2. A substrate treating method as defined in claim 1, further comprising cooling the substrate to normal temperature after said heating a substrate and before said removing the film.

3. A substrate treating method as defined in claim 1, wherein said heating is executed at a heating temperature in a range of 300 to 500° C.

4. A substrate treating method as defined in claim 2, wherein said heating is executed at a heating temperature in a range of 300 to 500° C.

5. A substrate treating apparatus comprising:
a heating unit for heating a substrate having an ion-implanted film formed on a surface thereof in an oxygen environment;
a removing unit for removing the film from the surface of the substrate by supplying a treating solution containing sulfuric acid and hydrogen peroxide solution or a treating solution containing ozone to the substrate after being in said heating unit; and
a transport mechanism for transporting the substrate from said heating unit to said removing unit.

6. A substrate treating apparatus as defined in claim 5, wherein said heating unit has a heating temperature set to a range of 300 to 500° C.

7. A substrate treating apparatus as defined in claim 5, wherein said heating unit includes a heat plate for supporting and heating the substrate, a chamber enclosing said heat plate, an oxygen supplying device for supplying oxygen gas into said chamber, a nitrogen gas supplying device for supplying nitrogen gas into said chamber, and a controller for controlling a feed rate of the oxygen gas from said oxygen supplying device and a feed rate of the nitrogen gas from said nitrogen gas supplying device, thereby to adjust an oxygen concentration.

8. A substrate treating apparatus as defined in claim 6, wherein said heating unit includes a heat plate for supporting and heating the substrate, a chamber enclosing said heat plate, an oxygen supplying device for supplying oxygen gas into said chamber, a nitrogen gas supplying device for supplying nitrogen gas into said chamber, and a controller for controlling a feed rate of the oxygen gas from said oxygen supplying device and a feed rate of the nitrogen gas from said nitrogen gas supplying device, thereby to adjust an oxygen concentration.

9. A substrate treating apparatus as defined in claim 5, wherein said removing unit includes a holding mechanism for holding one substrate at a time, an actuator for spinning said holding mechanism, and a treating solution supplying device for supplying the treating solution while the substrate held by said holding mechanism is spun by said actuator.

10. A substrate treating apparatus as defined in claim 6, wherein said removing unit includes a holding mechanism for holding one substrate at a time, an actuator for spinning said holding mechanism, and a treating solution supplying device for supplying the treating solution while the substrate held by said holding mechanism is spun by said actuator.

11. A substrate treating apparatus as defined in claim 7, wherein said removing unit includes a holding mechanism for holding one substrate at a time, an actuator for spinning said hold ing mechanism, and a treating solution supplying device for supplying the treating solution while the substrate held by said holding mechanism is spun by said actuator.

12. A substrate treating apparatus as defined in claim 8, wherein said removing unit includes a holding mechanism for holding one substrate at a time, an actuator for spinning said holding mechanism, and a treating solution supplying device for supplying the treating solution while the substrate held by said holding mechanism is spun by said actuator.

13. A substrate treating apparatus as defined in claim 5, wherein said removing unit includes a treating tank for storing the treating solution, and receiving the substrate, a treating solution supplying device for supplying the treating solution to said treating tank, and a lift mechanism movable between a treating position in said treating tank and a position above said treating tank while holding the substrate.

14. A substrate treating apparatus as defined in claim 6, wherein said removing unit includes a treating tank for storing the treating solution, and receiving the substrate, a treating solution supplying device for supplying the treating solution to said treating tank, and a lift mechanism movable between a treating position in said treating tank and a position above said treating tank while holding the substrate.

15. A substrate treating apparatus as defined in claim 7, wherein said removing unit includes a treating tank for storing the treating solution, and receiving the substrate, a treating solution supplying device for supplying the treating solution to said treating tank, and a lift mechanism movable between a treating position in said treating tank and a position above said treating tank while holding the substrate.

16. A substrate treating apparatus as defined in claim 8, wherein said removing unit includes a treating tank for storing the treating solution, and receiving the substrate, a treating solution supplying device for supplying the treating solution to said treating tank, and a lift mechanism movable between a treating position in said treating tank and a position above said treating tank while holding the substrate.

17. A substrate treating apparatus as defined in claim 5, wherein said transport mechanism includes an arm for holding the substrate, said arm having a cooling mechanism.

18. A substrate treating apparatus as defined in claim 6, wherein said transport mechanism includes an arm for holding the substrate, said arm having a cooling mechanism.

19. A substrate treating apparatus as defined in claim 7, wherein said transport mechanism includes an arm for holding the substrate, said arm having a cooling mechanism.

20. A substrate treating apparatus as defined in claim 8, wherein said transport mechanism includes an arm for holding the substrate, said arm having a cooling mechanism.
